(19) United States
(12) Patent Application Publication
(10) Pub. No.: US 2010/0163756 A1
(43) Pub. Date: Jul. 1, 2010

(54) Single event upset (SEU) testing system and method

(75) Inventor: Richard McPeak, Rancho Palos Verdes, CA (US)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Custom Test Systems, LLC.

(21) Appl. No.: 12/380,255

(22) Filed: Feb. 24, 2009

Related U.S. Application Data
(60) Provisional application No. 61/141,871, filed on Dec. 31, 2008.

(51) Int. Cl. G11C 29/52; G06F 3/048; G06F 12/16; H01J 37/08; G06F 12/02; G06F 11/00

(52) U.S. Cl. 250/492.21; 714/719; 715/771; 711/103; 714/723; 711/E12.008; 711/E12.103; 365/189.07; 714/E11.002

(57) ABSTRACT

One embodiment of the invention relates to a circuit board for testing upsets caused by charged particles delivered under testing conditions. The circuit board comprises a device under test including an internal memory, a memory control unit to generate test patterns for comparison with data read from stored areas within the internal memory of the device under test, and a memory that is configured to only store error data. Other embodiments are described and claimed.

This application claims the benefit of priority on U.S. provisional application No. 61/141,871 filed Dec. 30, 2008.

### FIELD

Embodiments of the invention generally relate to a system and method for testing memory devices, and in particular, the testing for particle induced data corruption on storage elements within an integrated circuit component.

### GENERAL BACKGROUND

Satellites in space are constantly bombarded by charged particles that can induce changes in the data content of semiconductor memories. This phenomenon is commonly referred to as a “single event upset” or “SEU”. While the placement of metal shielding around packaged memory may provide protection against single event upsets, such metal shielding is generally not practical because it adds extra launch weight to the satellite and increases the overall costs for such memories and satellite construction.

One solution in mitigating the likelihood of SEUs being experienced by semiconductor memories has been the use of “radiation hardened” integrated circuits. This type of integrated circuit is specifically designed for space application and is highly resistant to charge particle induced upsets. However, the satellite market is too small to support multi-billion dollar fabrication facilities needed to produce state of the art semiconductor memories for space application. Instead, the semiconductor memories are fabricated for general use, irrespective whether such use is in space or for commercial applications.

Therefore, when using semiconductor memories for space applications, satellite manufacturers simply test such devices to determine the probability and extent of data corruption and devise methods to detect and correct for such events. A device commonly referred to as an EDAC (Error Detection And Correction) is used to detect and correct errors in semiconductor memories. However, an EDAC has its own limitations.

One limitation is that, for use in error correction, an EDAC requires extra data bits for each data word. The complexity of the EDAC and the number of extra bits required for each data word increase greatly with the number of error bits that the EDAC is designed to detect and correct. It is generally not economically feasible to correct all of the errors in a large semiconductor memory. To determine whether or not a particular EDAC will be effective in detecting and correcting errors, it is necessary to understand how many errors are likely to be generated in the data words, and the timing of such errors.

For instance, consider the case of an EDAC that is adapted to detect up to three errors in a 16-bit data word and corrects at most two of those errors at a time. After performing an SEU test on a particular memory, it is found that there are a number of data words with four errors. Whether the EDAC can correct these errors had they occurred in an actual space application depends on the timing of the errors. If the four errors occurred one or two at a time, the EDAC could be used to correct them as long as the rate at which the EDAC scans the memory and fixes the errors is greater than the rate at which one or two errors are generated in any data word. If three errors are generated simultaneously, the errors could not be fixed, but at least the data could be flagged as corrupted. However, if a single charged particle changed the states of four (or more) bits in a single data word, then the EDAC would not detect that any error occurred regardless of its scan rater and the corrupted data could be used with serious consequences.

Hence, in an SEU test for a semiconductor memory, the device under test (DUT), namely the semiconductor memory itself, is written with a known data pattern and then it is subjected to a stream of charged particles. In order to economically and efficiently calculate the probability of particle induced upsets, the DUT is subjected to hundreds of thousands or millions of particles at a rate normally far greater than that found in space. To study the timing sequence of errors in the data words as described above, it is necessary to read and record the error data of the entire memory in less time than it takes for two particles to change the contents of any data word, and it is necessary to do this continuously throughout the test. Current testing techniques are incapable of performing such tests with a high level of accuracy on large semiconductor memories.

### BRIEF DESCRIPTION OF THE DRAWINGS

The patent or application file contains at least one drawing executed in color. Copies of this patent or patent application publication with color drawing(s) will be provided by the Office upon request and payment of the necessary fees. Features and advantages of embodiments of the invention will become apparent from the following detailed description in which:

FIG. 1 is an exemplary embodiment of a single event upset (SEU) testing system.

FIG. 2 is an exemplary embodiment of the test board of FIG. 1.

FIG. 3 is an exemplary embodiment of a more detailed view of the memory control circuit 220 of FIG. 2.

FIG. 4 is an exemplary flowchart illustrating the process operations performed by the memory and the memory control unit to upload of error data uncovered during the SEU test process.

FIG. 5 is an exemplary flowchart illustrating the operations performed by the computer and test board for retrieval of stored error data.

FIG. 6 is an exemplary embodiment of a flowchart illustrating the operations for storage of error data is shown

FIG. 7 is an exemplary embodiment of a flowchart illustrating the operations performed by the computer to display the transferred error data.

FIG. 8 is an exemplary embodiment of the display of errors detected across the entire memory within the device under test as generated by software stored within machine readable medium accessible by the computer of FIG. 1.

FIG. 9 is an exemplary embodiment of a detailed secondary view of an area of the memory within the device under test.

FIG. 10 is an exemplary embodiment of an expanded display of a row within the selected region illustrated in FIG. 9.

FIG. 11 is an exemplary embodiment of a dialog box generated by a program that enables the user to select the display color based on the number of detected errors within a column and/or row.

### DETAILED DESCRIPTION

Embodiments of the invention set forth in the following detailed description generally relate to a method, system and software for testing integrated circuits with storage elements, and in particular semiconductor memory devices, for particle induced data corruption. According to one embodiment of the invention, this testing is accomplished by analyzing the timing sequence for particle induced, single event upsets in a memory device as it is being subjected to a high intensity stream of charged particles (ions). According to this embodiment of the invention, the memory device is positioned on a test board along with on-board memory for storage of the test results. The on-board memory provides sufficient storage for continuously gathering many minutes of test results in real time.

As described below, in general, an embodiment of the Invention features a testing system that analyzes the sequence of particle induced, single event upsets in an integrated circuit with storage elements referred to herein as a “device under test” or “DUT”. The testing system reads the entire contents of the DUT continuously at high rates (e.g., up to and perhaps exceeding 9.6 billion bits per second as measured by reading up to 24 data bits at a 400 MHz data rate) and records at least all of the error data. Storage memory (e.g., multiple gigabits) and real-time error processing (so that only error data is saved) enables continuous testing over a longer period of time than would have occurred if all test data was saved. The error data is displayed graphically and can be filtered to restrict what error data is displayed based on a particular interest to the viewer.

In the following description, certain terminology is used to describe certain features of the invention. For instance, the term “computer” generally refers to any device with data processing capabilities. The terms “component,” “module” and “logic” generally refer to hardware and/or software configured to perform one or more functions. One example of a component is a storage element being any circuit that is adapted to store data (e.g., semiconductor memory, mini-disk drive, etc.). Another example of a component is circuitry that is adapted to store and process data (e.g., micro-controller, programmable logic array, microprocessor, application specific integrated circuit, a digital signal processor, etc.).

“Software” is generally defined as a series of executable instructions in the form of an application, an applet, or even a routine. The software may be stored in any type of machine readable medium such as a programmable electronic circuit, a semiconductor memory such as volatile memory (e.g., random access memory, etc.), or non-volatile memory such as any type of read-only memory “ROM”, flash memory, a portable storage medium (e.g., Universal Serial Bus “USB” drive, optical disc, digital tape), or the like.

In general, a semiconductor memory is an array of data words, where the location of each data word within the array is specified by a unique address. A “data word” is a series of data bits, usually fixed in number such as 2^{X} bits, where x≧3 (e.g. 8-bit, 16-bit, etc.).

It is contemplated that a “DUT” is a component with storage capability that is adapted for testing. For instance, according to one embodiment of the invention, the DUT may be an integrated circuit with semiconductor memory (e.g., a processor with cache memory, etc.). According to another embodiment of the invention, the DUT may be a packaged semiconductor memory for example. For these embodiments, the semiconductor memory is subject to errors caused by the charged particles altering a stored data bit from one logical value (e.g. “0” or “1”) to an opposite logical value (“1” or “0”).

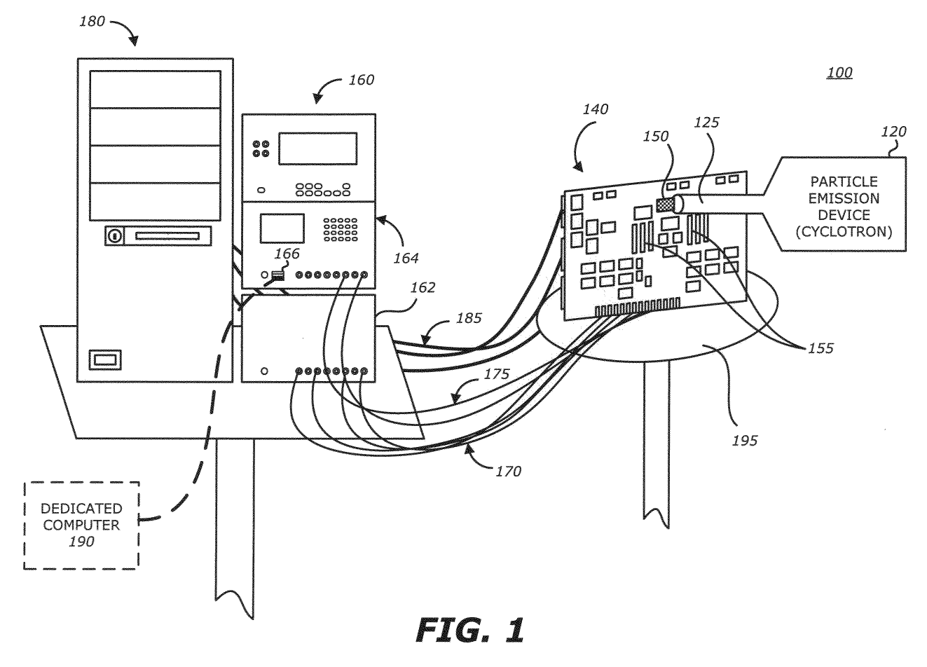

Herein, as shown in FIG. 1, an exemplary embodiment of a single event upset (SEU) testing system 100 is shown. SEC testing system 100 comprises (1) a particle emission device 120 that produces a stream of charge particles, (2) a test board 140 implemented with a device under test (DUT) 150, (3) power supply and measurement equipment 160, and (4) a computer 180. As an optional component, a dedicated computer 190 may be coupling to a connector (e.g., USB connector) of a meter forming part of power supply and measurement equipment 160. Dedicated computer 190, if implemented, is responsible for graphically depicting measured characteristics of the DUT in real-time. These characteristics may include, but are not limited or restricted to the amount of current measured or the amount of voltage measured at different inputs and/or outputs of the DUT.

As shown in FIG. 1, particle emission device 120 emits a focused stream of charged particles via a conduit 125 positioned proximate to and in front of DUT 150 mounted on test board 140. According to one embodiment of the invention, particle emission device 120 is a cyclotron or another particle accelerator that can be controlled to adjust (i) the rate at which particles are hitting DUT 150 and (ii) what mixture of particles formulates the stream. Hence, cyclotron 120 is capable of emulating space conditions. Such controls further enable testing system 100 to (i) better predict the upset probability (upset rate) in accordance with different kinds or different combinations of particles found in space and (ii) develop procedures to handle these upsets.

It is contemplated that the charged particles emitted from particle emission device 120 will lose some energy during propagation over the air to DUT 150. For certain particle emission devices, these charged particles have sufficient energy levels to still penetrate active circuitry within packaging of DUT 150. For those particle emission devices that emit low-energy ions, however, test board 140 may be placed within a vacuum chamber (not shown) that features connectors to allow for communications between test board 140 and both power supply and measurement equipment 160 and computer 180 to be maintained.

According to this embodiment of the invention, test board 140 features on-board memory 155 from which error data associated with each and every single event upset (SEU) experienced by storage elements of DUT 150 can be read within a very small amount of time. This “error data” includes the memory address that failed and the data currently within that memory address.

The initial storage of error data should not be stored by off-board memory because there is sufficient storage on test board 140 and usage of off-board memory unnecessarily exposes the test to inaccuracies caused by a loss of a portion of the error data during upload. Essentially, to conduct a high frequency test, it is useful for the contents to be read in a very small amount of time in order to detect all of the SEUs. For instance if the contents of the memory are being read every half second, the flow of ions should be adjusted so that it is unlikely that the same memory bit could be hit twice within the half second.

As shown in FIG. 1, test board 140 is a printed circuit board upon which DUT 150 is mounted. In general, test board 140 features onboard memory 155 that is configured to temporarily store error data that is caused by SEUs. The error data is subsequently transmitted to computer 180 over interconnect 185 without adversely affecting the storage of subsequent error data. Computer 180 features processing logic to process error data received from on-board memory 155 by executing a program that analyzes the error data and generates graphical depictions of the error data for easier understanding by the viewer as to what problems, if any, were experienced by DUT 150.

According to one embodiment of the invention, power supply and measurement equipment 160 comprises one or more power supplies 162 that are adapted to provide power to test board 140 and DUT 150 over interconnect 170. Power supply and measurement equipment 160 further comprises one or more meters 164 that are adapted to measure specific characteristics of DUT 150 and/or test board 140. These measured characteristics are provided to meter(s) 164 via interconnect 175.

As an optional feature, meter(s) 164 may be adapted with a connector 166 (e.g., USB connector) for coupling with dedicated computer 190. Dedicated computer 190 is responsible for graphically depicting measured characteristics of DUT 150 in real-time. These characteristics may include, but are not limited or restricted to the amount of current measured or the amount of voltage measured at different inputs and/or outputs of DUT 150.

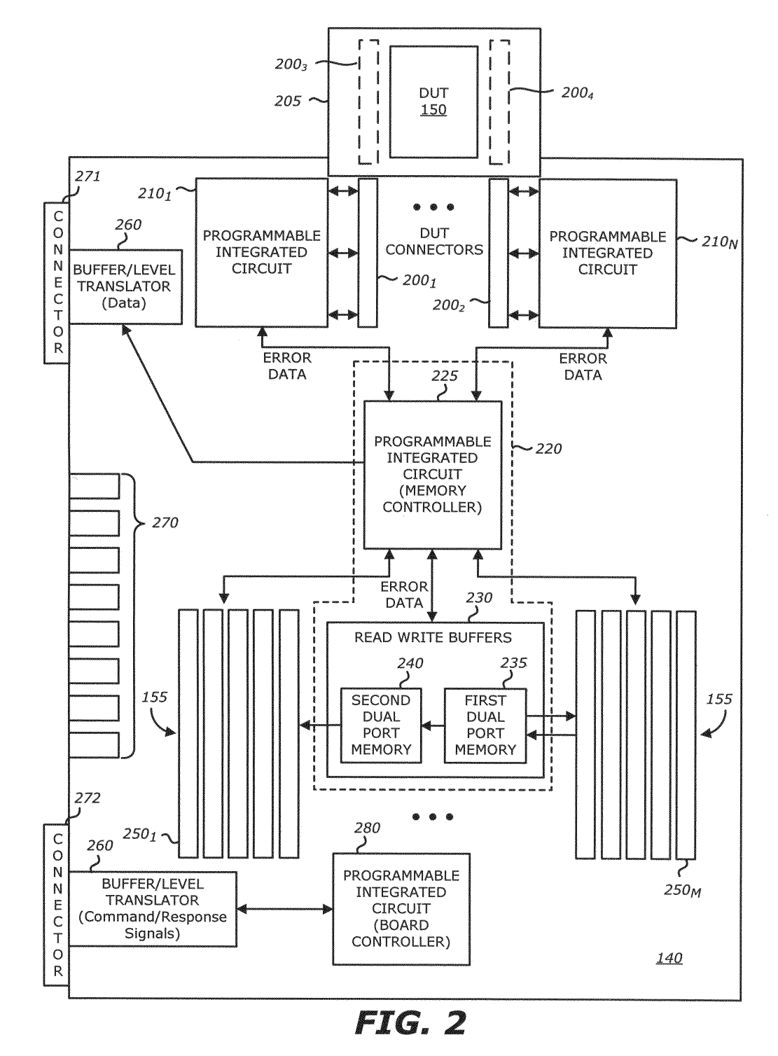

According to one embodiment of the invention, computer 180 is adapted to send commands to a controller of test board 140 (e.g., board controller 280 of FIG. 2 below) and provide an interface for the user to control and monitor the testing operations. Computer 180 also coordinates the transfer of error data from on-board memory 155 into memory resident on computer 180, processes the error data, and graphically displays the results. Because hundreds of gigabits of data can be generated for a single SEU test, computer 180 is adapted to filter the processed data as directed by the user. For example, if the user's EDAC can correct two errors in a data word, the user could choose to view only the memory locations where three of more errors occurred with color and texture being used to indicate different levels of error.

For testing purposes, as an option, test board 140 may be positioned on an adjustable table 195 in order to alter the location of DUT 150 during testing. This causes the angular direction of the charged particles emitted from particle emission device 120 to be altered, especially where the position of the particle emission device 120 is rotated along an X-Y plane, X-Z plane, Y-Z plane or any combination thereof. Hence, the charged particles penetrate the memory within DUT 150 at different angles and in accordance with different ion penetration paths, where these differences may cause data within memory of DUT 150 to be corrupted. Alternatively, in lieu of adjustable table 195, particle emission device 120 may be adjustable to allow for ion penetration into active circuitry of DUT 150 at different angles.

Referring now to FIG. 2, an exemplary embodiment of test board 140 is shown. Herein, test board 140 is a printed circuit board that comprises metal traces for interconnecting components mounted thereon. According to this embodiment of the invention, test board 140 comprises one or more (N≧1) DUT connectors 200₁-200_{N} (e.g. N≧2), programmable integrated circuit(s) 210₁-210_{N}, a memory control circuit 220, on-board memory 155, buffer and level translator circuitry 260, one or more peripheral connectors 270-272, and a board controller 280.

As shown in FIG. 2, DUT 150 is mounted on a top surface of an adapter 205 while connectors 200₃-200₄ are situated on a bottom surface of adapter 205. Connectors 200₃-200₄ are coupled to corresponding connectors 200₁-200₂ of test board 140 so that connectors 200₃-200₄ establish an electrical connection between the DUT (i.e. DUT 150 of FIG. 1) and certain components of test board 140 such as programmable integrated circuits 210₁-210₂.

In particular, according to one embodiment of the invention, DUT 150 is soldered to the top surface of adapter 205, which is a printed circuit board. Where DUT 150 is a packaged semiconductor device, the plastic package and the substrate placed over the active circuitry are etched away in order for expose the active circuitry and direct charged ions from any direction onto this active circuitry. According to other embodiments of the invention, DUT 150 is surface mounted to test board 140, and connectors 200₃-200₄ are considered to be solder joints establishing such connections, or DUT 150 is mounted on a separate daughter card and connectors 200₁-200₂ collectively operate as an edge connector for the daughter card. According to yet another embodiment of the invention, the DUT may be placed within a socket 204 mounted on test board 140.

Herein, programmable integrated circuits 210₁-210₂ are used to generate test patterns and such patterns are compared with data read from stored areas within semiconductor memory of DUT 150. This comparison is conducted to determine whether or not any storage errors have been caused by the charged particles emitted from particle emission device 120 of FIG. 1. If an error is detected, the error data is routed to memory control circuit 220 from whatever programmable integrated circuit 210₁ or 210₂ detected the error.

It is contemplated that, according to one embodiment of the invention and as shown in FIGS. 1 and 2, a viewer can select the test pattern to be conducted. For this embodiment, a menu listing the available test patterns is displayed at computer 180 of FIG. 1. The viewer selects a test pattern from the list of test patterns. Once that test pattern is selected, the computer sends that information to board controller 280, which signals the circuitry writing the test patterns into storage elements of the DUT (e.g., programmable integrated circuits 210₁-210₂) to utilize the selected test pattern for the next test cycle. Alternatively, the test patterns could be pre-stored or automatically generated in real-time by components on test board 140 in lieu of being selected by the viewer.

It is further contemplated that the error data is routed to memory 155 placed on test board 140 in order to avoid problems associated with storage in the computer such as, for example, limited on-board memory with slow transfer rates to the computer disc drive, slow data transfer rates to the computer caused by connector induced noise in a vacuum chamber, and the like. Hence, it would be advantageous to leave the computer free to process and display data during the testing process. Of course, as an alternative to the described test board 140, memory 155 may be placed on a separate board in communication with test board 140, provided the level of noise caused by interconnects to the board is suitable.

Therefore, in order to perform the high frequency operations as described, DUT 150 should be tested once it is coupled to test board 140 and the lead lengths are dramatically reduced by the use of traces within test board 140. Herein, the lead lengths the programmable integrated circuits are as short as possible, and typically less than a few inches in length (e.g., 10 inches or less). The data is stored transmitted to on-board memory (e.g., on-board (and off-chip) memory within computer 180 at slower rates because a wider bus may be used for such transmissions.

Referring back to FIG. 2, memory control circuit 220 includes a programmable integrated circuit 225 operating as a memory controller and one or more read/write buffers 230. Memory control circuit 220 is adapted to store the error data into on-board memory 155, namely a plurality (M) of memory modules 250₁-250_{M} that include volatile memory that is refreshed by memory control circuit 220 as needed. However, before storage within on-board memory 155, memory controller 225 routes the error data for temporary storage in read/write buffer 230.

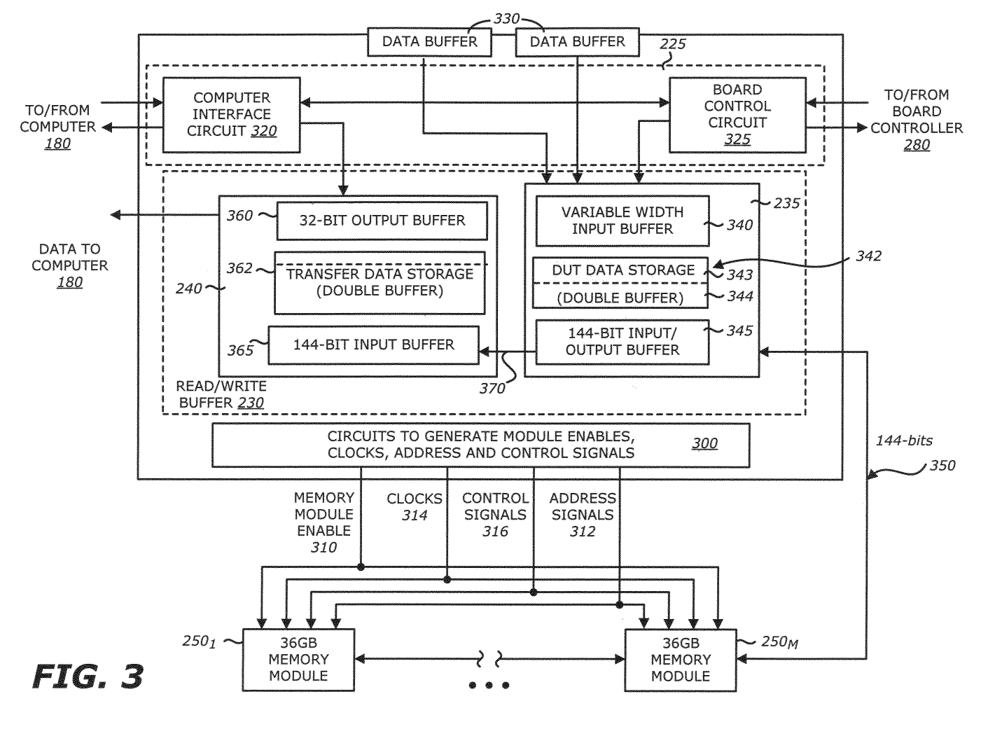

According to one embodiment of the invention, read/write buffer 230 comprises a first dual-port memory 235 operating as a double buffer. First dual-port memory 235 includes a first (DUT-side) port and a second (memory-module-side) port as described in detail in FIG. 3. The first port is in communication with a variable-width bus, where the configured width depends of the number of DUT outputs. The second port is in communication with a bus through which data is loaded and retrieved from on-board memory 155. Read/write buffer 230 further comprises a second dual-port memory 240 that also operates as a double buffer. However, second dual-port memory 240 transfers data received from memory modules 250₁-250_{M} to computer 180 of FIG. 1 via connector 271.

Herein, read/write buffer 230 operates by determining when a specified portion (e.g., one-half) of first dual-port memory 235 is full so that incoming DUT data is directed to the remaining portion (e.g., remaining half) of first dual-port memory 235 while the contents of the filled portion of first dual-port memory 235 are stored in memory modules 250₁-250_{M}. The circuit timing may be designed so that the contents of the filled portion of first dual-port memory 235 is stored in memory modules 250₁-250_{M} before the other portion of first dual-port memory 235 can be filled with incoming data. When the remaining portion (e.g., second half) of first dual-port memory 235 is filled, its contents are stored while new input data is directed to the now-empty first portion of first dual-port memory 235. By switching back and forth between multiple portions of first dual-port memory 235, DUT data is read continuously so that no incoming data is lost while downloading data to memory modules 250₁-250_{M}.

As further shown in FIG. 2, test board 140 comprises power/meter connector 270 that provide the power for test board 140 and the DUT. Connector 270 also allows the meters to monitor the currents and/or voltages experienced by DUT 150.

Buffer and level translator circuitry 260 is adapted to condition data signals for transfer to computer 180 via connector 271 and to condition control signals from/to computer 180 via connector 272. These control signals may include commands to perform refresh, coordinate the transfer of error data from on-board memory 155, process the error data, and graphically display the results.

As an optional component, test board 140 comprises board controller 280, namely a programmable integrated circuit that interfaces with computer 180 of FIG. 1 and controls the functionality of test board 140. According to this embodiment of the invention, board controller 280 receives commands from computer 180 via connector 272 and translator circuitry 260, acknowledges the commands, provides status reports to computer 100, loads programmable integrated circuits 210₁-210_{N} on test board 140 with necessary patterns, monitors the status of the other programmable circuits and generates status displays that can be read by the user for troubleshooting problems. As an alternative, board controller 280 may be situated on a separate board such as a daughter card.

Referring to FIG. 3, a more detailed view of an embodiment of memory control circuit 220 is shown. According to this embodiment of the invention, memory control circuit 220 comprises memory controller 225 and read/write buffer 230 as well as circuitry 300 to provide Enable, Clock, Address and Control signals to on-board memory 155. In particular, circuitry 300 may be configured to generate one or more Enable signals 310 for selecting corresponding memory module(s) 250₁ . . . , or 250_{M} to receive error data. The memory modules 250₁-250_{M} are selectively read from or written into a memory address identified by Address signals 312. Clock and control signals 314 and 316 are used for refreshing memory modules 250₁-250_{M}.

In other words, the clocks, enable inputs, address inputs, control inputs and data bus inputs/outputs are used to initialize and configure memory modules 250₁-250_{M}, write data into them, read data from them and refresh their contents. For this embodiment of the invention, clock signals 314 continuously run during normal operations and they provide the reference point for all of other inputs into memory modules 250₁-250_{M}. Enable signals 310 select which of memory modules 250₁-250_{M} is active at any time for reading, writing or refreshing data. The address inputs 312 specify which memory locations in the selected memory module 250₁ . . . or 250_{M} are used for writing or reading data. The data bus signals are used as both inputs and outputs. When writing data to memory modules 250₁-250_{M}, the data bus signals are configured as outputs from memory controller 225 (inputs to the selected memory module) and are forced by memory controller 225 with data to be written into the selected memory module. When reading data from memory modules 250₁-250_{M}, the data bus signals are configured as inputs into memory controller 225 (outputs from the selected memory module) and are forced by the selected memory module with data to be written into memory controller 225.

As shown, memory controller 225 includes a computer interface circuit 320 that receives and transfers control signals with computer 180 of FIG. 1 in order to coordinate the transfer of error data obtained from one of memory modules 250₁-250_{M} and temporarily stored in read/write buffer 230 prior to output. Memory controller 225 further comprises a board control circuit 325 adapted to receive commands from board controller 280 of FIG. 2 and return status. For example, board controller 280 may transmit a command to alter storage areas so that the second storage portion of first dual-port memory 235 is adapted to receive the error data white error data within the first storage portion is downloaded to memory modules 250₁-250_{M}.

As shown in one embodiment of the invention, first dual-port memory 235 comprises a variable width input buffer 340, a double buffer 342 and an input/output (I/O) buffer 345. Variable width input buffer 340 is sized to receive error data from one or more optional data buffers 330 that are adapted to temporarily store error data from programmable integrated circuit(s) in communication with the DUT.

Herein, when a first portion 343 of double buffer 342 is full, the incoming DUT data is directed to a second portion 344 of double buffer 342 while the contents of first portion 343 are stored in memory modules 250₁-250_{M}. It is contemplated that the contents of first portion 343 of double buffer 342 may be stored in memory modules 250₁-250_{M} prior to filling second portion 344 of double buffer 342 with incoming data. However, in certain instances, it is contemplated that filling of the second portion 344 may be at least partially filled before storing the error data in first portion 343 into memory modules 250₁-250_{M}.

When second portion 344 of double buffer 342 is filled, its contents are stored while new input data is directed to the now-empty first portion 343 of first dual-port memory 235. By switching back and forth between the two portions of double buffer 342, DUT data is read continuously and no incoming data is Lost while downloading data to memory modules 250₁-250_{M}.

I/O buffer 345 is adapted with a larger bit width than double buffer 342 in order to transmit the error data in bursts over a bus 350 that is sized with a bit width exceeding the bit width of variable width input buffer 340. For instance, as an illustrative embodiment, variable width input buffer 340 is 32-bits wide while I/O buffer 345 is 144-bits wide for output of 144-bit data packets onto bus 350 via the second port (memory-module side port).

Also operating as a double buffer for data download to the computer, read/write buffer(s) 230 comprises an output buffer 360, a double buffer 362 and an input buffer 365. Double buffer 362 enables the cycling between the storage and transmission of error data to the computer. Although not shown, a first (memory-module-side) port is in communication with a 144-bit bus 370 through which data is loaded and retrieved from on-board memory 155 (e.g., modules 250₁-250_{M}) for uploading into input buffer 355. A second (computer-side) port is in communication with output buffer 360 for formatting the error data within double buffer 362 as 32-bit data packets before commencing a downloading operation to the computer.

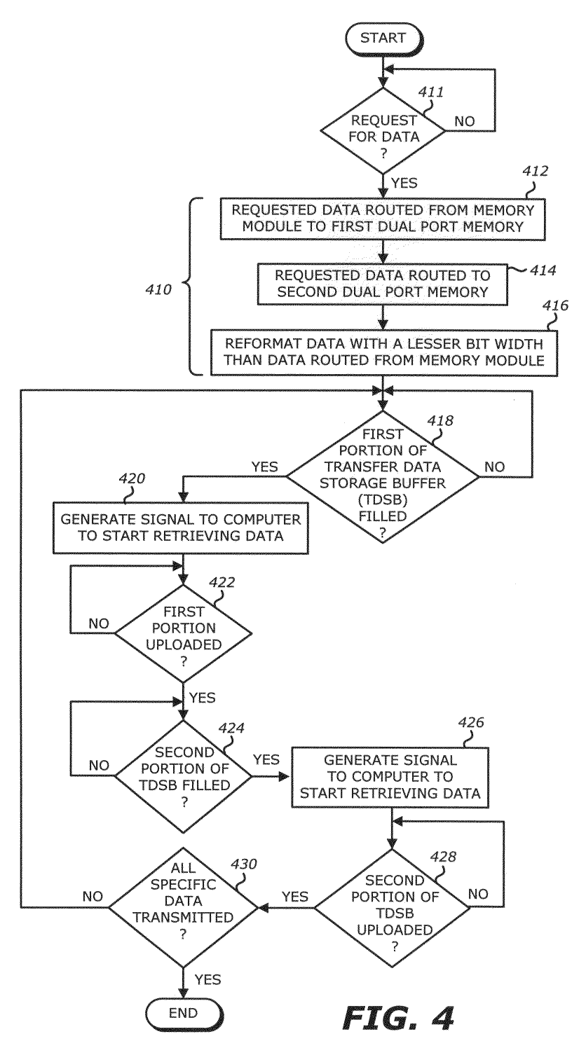

Referring now to FIG. 4, the process of transferring data to the computer begins with a request from computer 180 for data starting at a specified point in the data stream (block 400). Data from memory locations associated with the specified point in the data stream is transferred from the memory modules into the read/write buffer (block 410). More specifically, the requested data is routed over a data bus as data packets of a first bit width (e.g., 144-bit payloads) and into the first dual-port memory (block 412). Thereafter, the data packets of a first bit width are routed to the second dual-port memory and subsequently reformatted into packets of a second bit width (blocks 414 & 416). The second bit width (e.g., 32-bits) is lesser in size width than the first bit width (e.g., 144-bits).

Once a first portion of the double buffer within the second dual-port memory is filled, a signal is generated from the test board indicating to the computer that it can start retrieving data (blocks 418 & 420). After the first portion of the double buffer of the second dual-port memory is uploaded to the computer, the data transfer continues to the other portion of the double buffer (blocks 422, 424, 426). The process continues until all of the specified data is transferred (blocks 428 and 430). Of course, if the memory controller is storing data and too busy to retrieve data, it generates a “Wait” signal. The computer monitors for this signal and stops transferring data whenever the Wait signal is active.

The storage of data and the transfer of previously stored data are two independent processes in memory control circuit 220 of FIG. 2. For this embodiment of the invention, the storage of DUT error data is assigned a higher priority, but if the memory control circuit is not utilized full-time storing data, it will interleave the storage of data into the memory modules with the transfer of data out of sucn memory. Since all of the error data is stored on the printed circuit board, the computer is free to use its entire available memory to process and display data while the SEU test is in progress.

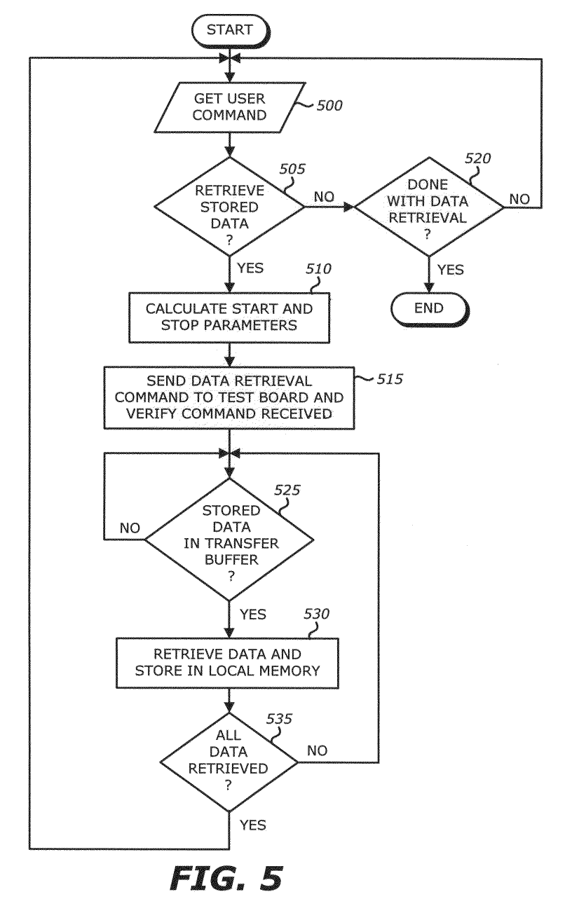

Referring now to FIG. 5, an exemplary embodiment of operations for retrieval of stored data is shown. Initially, a determination is made whether the DATA RETRIEVAL command is to be initiated to the testing system (blocks 500 and 505). If so, parameters are provided for insertion within the DATA RETRIEVAL command in order to identify where (e.g. memory location(s)) the requested data is stored in the memory modules (block 510). Thereafter, the DATA RETRIEVAL command is transmitted to the test board (block 515). Where the command is not a DATA RETRIEVAL command, the computer continues with its operations unrelated to data retrieval until the data retrieval has been completed (block 520).

In the event that the DATA RETRIEVAL command is received by the test board, the data identified in the DATA RETRIEVAL command is fetched from the memory modules for subsequent storage within the output buffer of the memory control circuit (blocks 525 and 530). The coordination of the download of the error data stored within the output buffer is performed by communications between the computer and the board controller, where the error data is retrieved until all of the error data stored within the output buffer is routed to memory on the computer (block 535).

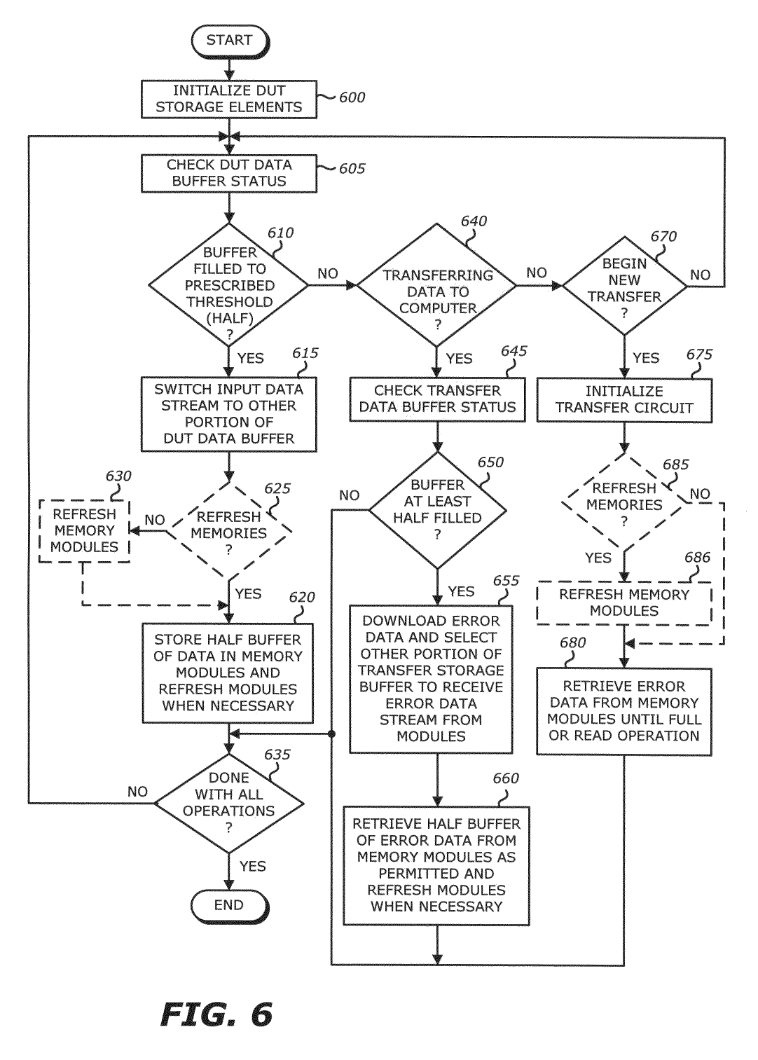

Referring now to FIG. 6, an exemplary embodiment of a flowchart illustrating the operations for storage of error data is shown. At system start-up, the storage elements containing the DUT data are initialized (block 600). Thereafter, the buffer status of the DUT is checked to determine whether the DUT data (double) buffer is filled up to a prescribed threshold (blocks 605 and 610). For instance, as an illustrated example, the determination is made whether the DUT data buffer is half-filled.

In the event that the DUT data buffer is filled up to a prescribed threshold, the downloaded error data stream is altered to begin filling the other portion of the DUT data buffer while the portion of the DUT data buffer that is filled up to the prescribed threshold is stored in the memory modules (blocks 615 and 620).

In the event that the memory modules are formed with volatile memory that require refresh signaling, these memories are refreshed before or after storage of the error data into the memory modules (blocks 625 and 630). This process continues until all of the storage operations have been completed (block 635).

In the event that the DUT data buffer is not filled to a prescribed threshold, a determination is made whether, at this time, data can be transferred to the computer (block 640). By checking the status of the transfer data buffer (double buffer 362 of FIG. 3), a determination can be made whether the buffer is filled at least up to a prescribed level, such as at least half filled for example (see blocks 645 and 650). If so, the data is downloaded from a first portion of the transfer data buffer as permitted until the first portion of the buffer is empty and the second portion is adapted to receive additional uploaded data (blocks 655 and 660). Of course, the memory modules are refreshed as necessary during this error data uploading process.

In the event that the DUT data buffer is not filled to the prescribed threshold and error data is not scheduled to be transferred to the computer at this time, a determination is made whether a new transfer from the memory modules to the transfer data buffer may commence (block 670). If So, the transfer circuitry is in initiated and error data is retrieved from the memory modules as permitted until error data is to be read into memory modules or the transfer data buffer is full (blocks 675 and 680). In the event that the memory modules are formed with volatile memory that require refresh signaling, these memories are refreshed before or after retrieval of the error data from the memory modules (blocks 685 and 686).

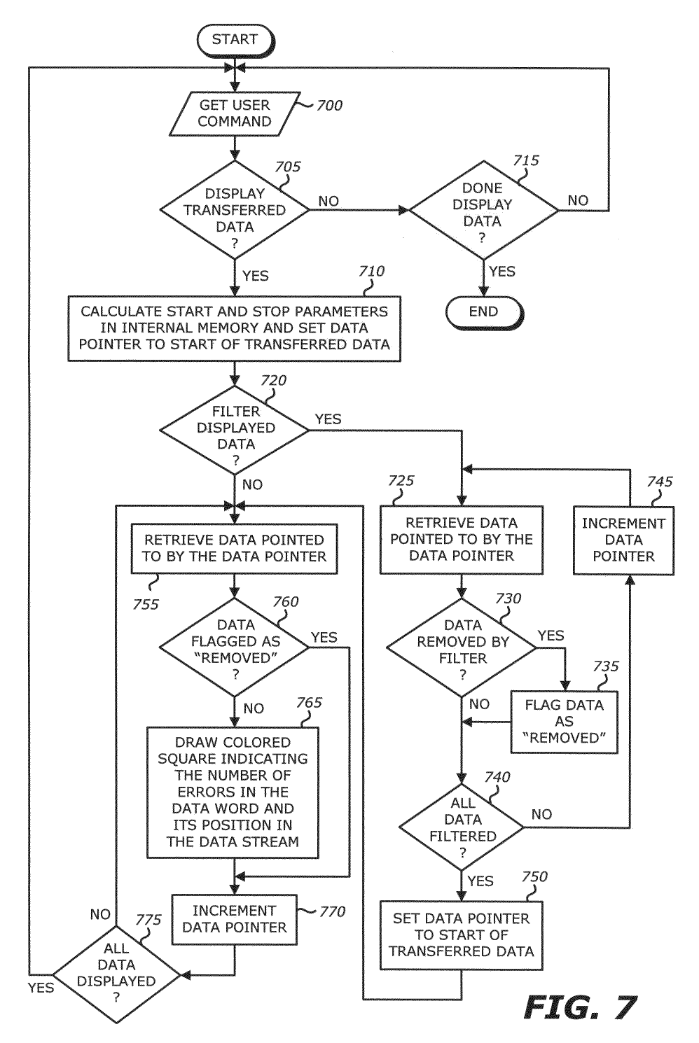

Referring now to FIG. 7, an exemplary flowchart illustrating the operations performed by the computer to display the transferred error data is shown. Herein, a command is initiated by the user to the test system (block 700). Based on this command, a determination is made whether the command is a DISPLAY command (block 705). If so, the start and stop parameters for error data within the internal memory are calculated and a data pointer is set to the start parameter (block 710). If the command is not a DISPLAY command, the computer continues with its operations unrelated to displaying data retrieval (block 715).

A determination is made whether the displayed data is to be filtered (block 720). If so, error data pointed to by the data pointer is retrieved and such error data determined whether it should be filtered (blocks 725 and 730). If so, the data is flagged as “removed” (block 735). If all of the error data has not been analyzed for filtering, the data pointer is incremented to retrieve additional error data (blocks 740 and 745). Thereafter, the additional error data now pointed to by the data pointer is determined whether to be filtered. This process continues until all of the display data has been exposed to this filtering scheme (block 750).

Once the data to be displayed has been filtered (or if no filtering is desired), the error data pointed to by the data pointer is retrieved (block 755), and if not flagged for removal, the data pointer is assigned a color to indicate the number of errors in the data word and the position of the data word within the data stream (blocks 760 and 765). Thereafter, the data pointer is incremented and the display of such additional error data continues until all of the error data has been displayed (blocks 770 and 775).

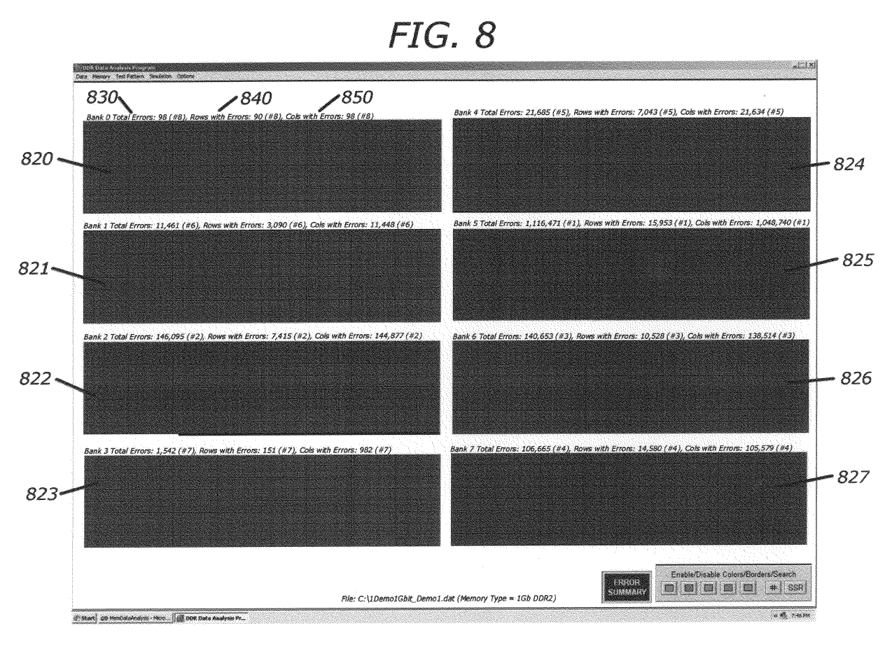

Referring now to FIG. 8, an exemplary embodiment of a display 800 produced on a display monitor and generated by a processor operating on software stored within machine readable medium accessible by computer 180 of FIG. 1. This software, referred to as the “SEU analysis program,” generates one or more displays that utilize color and/or texture to represent which areas of memory have experienced particle induced data corruption.

According to this embodiment of the invention, software within computer 180 of FIG. 1 processes the error data received from test board 140 and generates a display 800 that graphically depicts SEUs detected within the memory of DUT 150. This display may be generated after completion of the testing or may be generating during such testing as error data is received. Different colors and textures may be used to indicate the number of errors detected for a particular area in memory. For instance, in this embodiment, a first color (e.g., green) may be used to represent the particular area of memory is free from errors. A second color (e.g., red) may be used to represent an area of memory that has experienced an unacceptable number of errors. Intermediary colors may be used to represent different areas of memory that have experienced errors, but such errors are within an acceptable range for instance.

Of course, in lieu of number of errors, the color representation may be based, at least in part, on whether the particular memory location is designed to store programs critical to the operations of the device (satellite). Hence, a single SEU within a data word of this memory location may be assigned the second color while, if the SEU occurred in another memory location, an intermediary color would have been assigned.

Herein, according to this embodiment of the invention as shown in FIG. 8, display 800 illustrates the tested memory within DUT 150 as multiple memory banks 810 (e.g., bank0 820-bank7 827) along with computations for each of banks 820-827. Each bank 820-827 is illustrated as a collection of units, each representing a row of memory and being illustrated as a separate geometric shape such as a square, circle or the like.

Herein, a single unit 820₁ within bank0 820 corresponds to a row, namely 2048 columns of memory where each column includes one data word such as a byte of memory for example. The computations for each of banks, such as bank0 820, identify (i) total errors 830, (ii) number of rows with errors 840, and (iii) number of columns with errors 850.

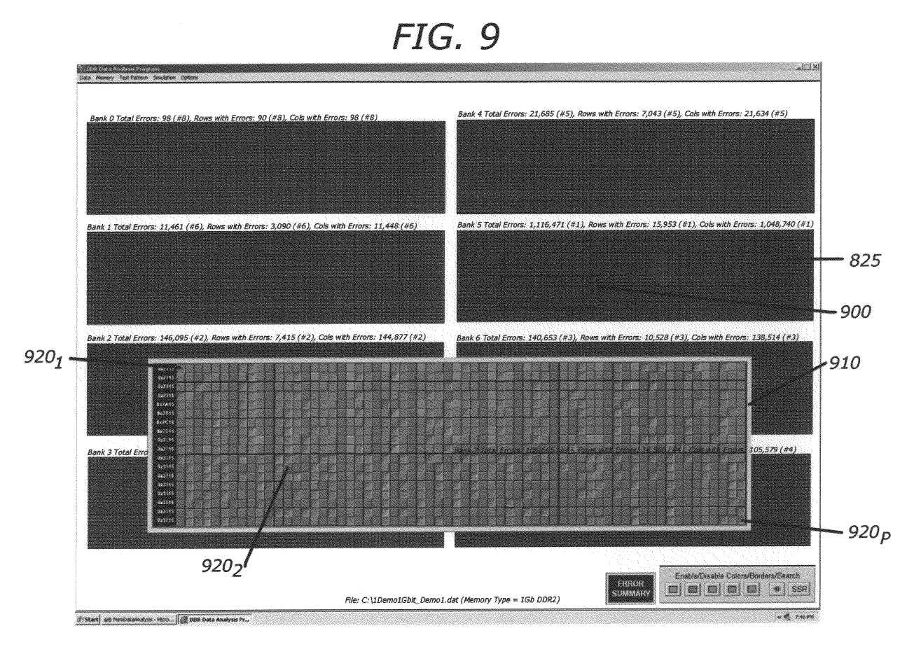

Referring to FIG. 9, an exemplary embodiment of a detailed secondary view represented by tiles forming an area of memory within the DUT is shown. Herein, a region 900 within memory bank5 825 is selected using an input device (e.g., a mouse, touch pad, stylus, touch screen) of the computer. This causes the SEU analysis program to expand region 900 and render a sub-display 910. Sub-display 910 illustrates the “rows” 920₁-920_{P} (P≧2) forming region 900. Each row 920₁, . . . , or 920_{P} constitutes approximately 16 kilobytes (kB) of memory for this embodiment, although it is contemplated that each row may be assigned to more or less memory than illustrated. For instance, as an illustrative example, each row constitutes a plurality of columns, such as 2048 columns, and is represented using the above-described color and/or texture based on the number of errors detected within the channels formulating the row. Herein, row 920₂ is represented by a second color (e.g., red) to indicate that an unacceptable number of SEUs were detected for this area of memory.

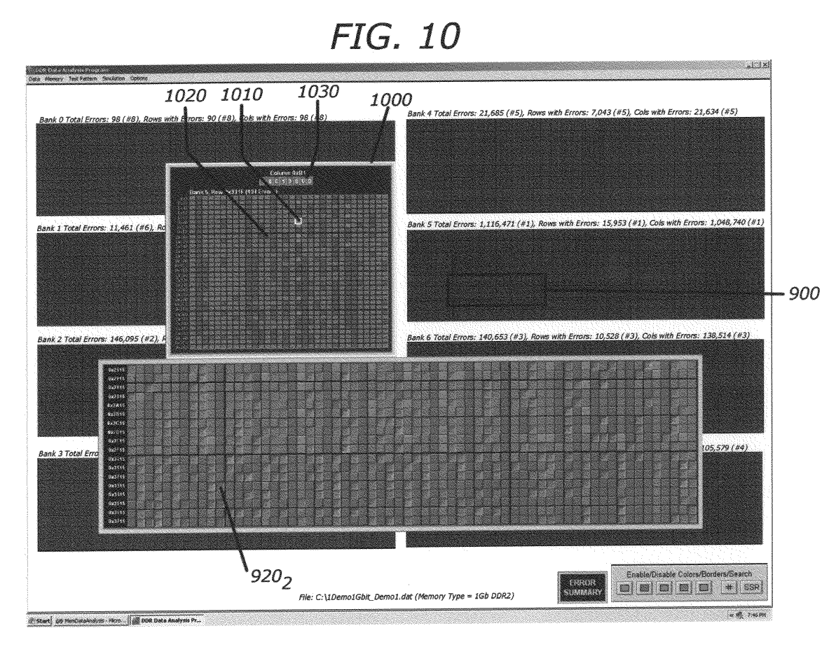

FIG. 10 is an exemplary embodiment of an expanded display of row 920₂ within selected region 900 of FIG. 9. According to this embodiment of the invention, row 920₂ of region 900 is formed of 2048 columns, which are generally shown in sub-display 1000 after selection of row 920₂. Herein, column 1010 is represented by an intermediary color (e.g., blue) to denote that column 1010 experienced a greater number of errors than column 1020.

The content within one of these columns (e.g., column 1010) is shown as a data word in sub-display 1030. The bits in column 1010 that are correct (e.g., bits 7-6, 4, 2, 0) are represented with a background having a first color (e.g., green) while those bits that have corrupted (incorrect) data (e.g., bits 5, 3, 1) have been represented with a background having a second color (e.g., red). These graphical depictions allow the user to more quickly analyze what portions of the memory have experienced the most SEUs and to even determine which bits experienced SEUs.

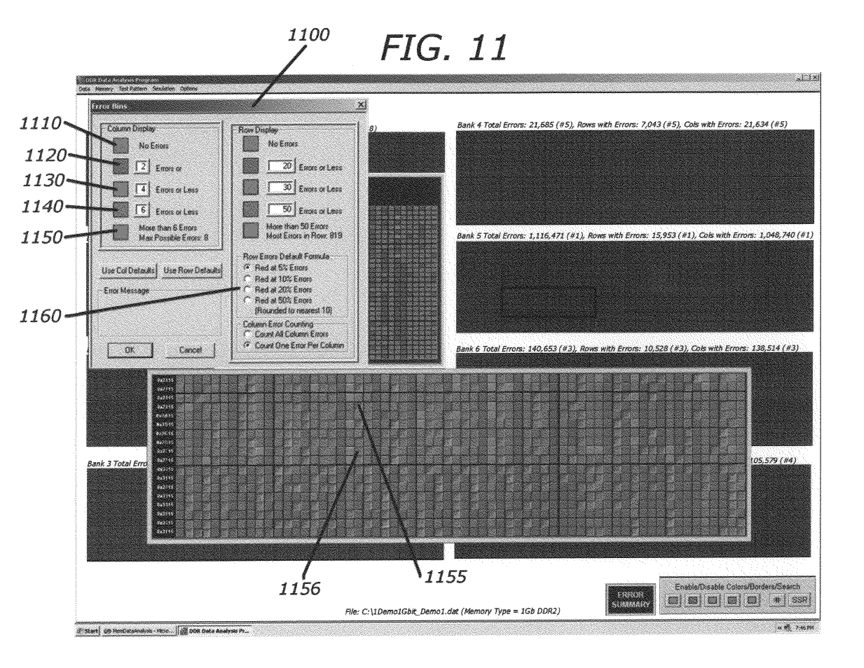

Referring to FIG. 11, an exemplary embodiment of a dialog box 1100 generated by the SEU analysis program to enables the user to select the display color based on the number of detected errors within a column and/or row. Herein, dialog box 1100 is generated based on selection using either a menu option or another user-based input. Dialog box 1100 allows multiple colors such as a first color 1110 being used by both rows and columns if no errors are detected. A second color 1120 is used by both rows and columns if at most 20 and 2 errors are detected, respectively. A third, fourth and fifth colors 1130-1150 are used to indicate if a row has experienced at most 30, 50 and over 50 errors while these same colors are used to indicate if a column has experienced at most 4, 6 and more than 6 errors, respectively. These error values can be set by the user.

As shown, texture could be used to represent different levels of errors and/or severity. Herein, the term “texture” describes the visual perception of the surface of the displayed image. For instance, the surface of a row with a high number of errors may be represented as having more depth or being non-uniform than the surface for a row with no or a lesser number of errors.

For instance, as an illustrative embodiment, depth levels may be used to visually identify which particular row(s) has (have) a greater number of upsets. As an illustrative example, row 1155 has more depth than row 1156, and thus, is displayed as having a greater number of upsets than row 1156. Alternatively, the surface of a row with a higher number of errors may be represented as having a particular pattern that differs from surfaces with no or a lesser number of errors. Another alternative embodiment involves the use of color intensity to represent error ranges or the use of animation (image movement) to identify a certain error measurement. Another alternative embodiment would be to oscillate (e.g., vibrate) a particular row to identity a particular event (e.g., number of errors, a type of error that occurred for that row in a previous test, etc.).

As shown in FIG. 11, dialog box 1100 further provides an option 1160 to use defaults to identify degrees of errors within a particular memory area (e.g., row and/or column). As shown, the defaults are based on a percentage of errors detected for a particular memory area (row and/or column).

While the invention has been described in terms of several embodiments, the invention should not be limited to only those embodiments described, but can be practiced with modification and alteration within the spirit and scope of the appended claims. For instance, the DUT can be mounted on an adapter that is attached to one end of a cable with the other end of the cable is coupled to the test board. This will enable the DUT to be exposed to environments that would normally harm the test board such as electron bombardment, proton bombardment and gamma rays. For these types of tests, the test board should be protected from the environment. To do that, the DUT should be mounted on an adapter, which is connected to the test board with a cable.

What is claimed is:

1. A circuit board comprising:
a device under test including an internal memory;
a memory control unit to generate test patterns for comparison with data read from stored areas within the internal memory of the device under test; and
a memory that is configured to only store error data.

2. The circuit board of claim 1, wherein the memory control unit comprises a programmable integrated circuit operating as a memory controller and at least one read/write buffer.

3. The circuit board of claim 2, wherein the at least one read/write buffer comprises a first dual-port memory.

4. The circuit board of claim 3, wherein the first dual-port memory of the at least one read/write buffer includes a first port in communication with a variable-width bus and a second port in communication with a bus through which data is loaded and retrieved from the memory.

5. The circuit board of claim 3, wherein the at least one read/write buffer comprises a second dual-port memory to enable a transfer of the error data from the memory.

6. The circuit board of claim 1 further comprising a board controller adapted to receive commands from a computer.

7. A system comprising:
a particle emission device to emit a stream of charged particles; and
a circuit board including a device under test situated within a path of the stream of charged particles, the device under test including an internal memory having areas that store data, (ii) a memory control unit to generate a test pattern for comparison with the data read from the areas of the internal memory, and a memory that is configured to only store error data computed from the comparison of the data and the test pattern.

8. The system of claim 7, wherein the memory control unit of the circuit board comprises a programmable integrated circuit operating as a memory controller and at least one read/write buffer.

9. The system of claim 8, wherein the at least one read/write buffer of the memory control unit comprises a first dual-port memory.

10. The system of claim 9, wherein the first dual-port memory of the at least one read/write buffer includes a first port in communication with a variable-width bus and a second port in communication with a bus through which data is loaded and retrieved from the memory.

11. The system of claim 9, wherein the at least one read/write buffer of the memory control unit comprises a second dual-port memory to enable a transfer of the error data from the memory.

12. The system of claim 7, wherein the circuit board further comprises a board controller adapted to receive commands from a computer.

13. A computer comprising:
a display monitor; and
a processor to (i) receive error data from a circuit board adapted with an integrated circuit with internal memory that is situated to receive a controlled stream of charged particles, and (ii) generate a representation of storage areas within the internal memory for display on the display monitor, the representation indicating what portions of the storage areas of the internal memory have experienced errors caused by the controlled stream of charged particles.

14. The computer of claim 13, wherein the representation generated by the processor uses color to distinguish between different ranges of errors.

15. The computer of claim 13, wherein the representation generated by the processor uses texture to distinguish between different ranges of errors.

16. The computer of claim 15, wherein the texture is a depth level of tiles forming the representation.

17. The computer of claim 15, wherein the texture is an oscillation of a particular tile of the representation.
